(19) United States
(12) Patent Application Publication
(10) Pub. No.: US 2007/0241341 A1
(43) Pub. Date: Oct. 18, 2007

(54) LIGHT REFLECTING DEVICE WITH STRAY LIGHT EXTINCTION CAPABILITY

(75) Inventor: Yan-Hong LIU, Taichung (TW)

Correspondence Address: MCNEES WALLACE & NURICK LLC, 100 PINE STREET, P.O. BOX 1166, HARRISBURG, PA, 17108-1166, US

(73) Assignee: ASIA OPTICAL CO., INC., Taichung (TW)

(21) Appl. No.: 11/668,318

(22) Filed: Jan. 29, 2007

(30) Foreign Application Priority Data
Apr. 17, 2006 (TW) 095113649

(51) Int. Cl. H01L 33/00

(52) U.S. Cl. 257/79

(57) ABSTRACT

A light reflecting device includes: a substrate having front and back surfaces; a light absorbing layer formed on a selected one of the front and back surfaces of the substrate; a buffer layer formed on the light absorbing layer when the light absorbing layer is formed on the front surface of the substrate and on the front surface of the substrate when the light absorbing layer is formed on the back surface of the substrate; and a light reflecting layer formed on the buffer layer. The light absorbing layer has an extinction coefficient greater than 0.15 and a layer thickness ranging from 10 to 500 nm.

### CROSS-REFERENCE TO RELATED APPLICATION

This application claims priority of Taiwanese Application No. 095113649, filed on Apr. 17, 2006.

### BACKGROUND OF THE INVENTION

1. Field of the Invention

This invention relates to a light reflecting device, more particularly to a light reflecting device having a light absorbing layer for extinguishing stray light.

2. Description of the Related Art

FIG. 1 illustrates a conventional light reflecting device 1 that includes a substrate 11 having a front surface, a buffer layer 14 formed on the front surface of the substrate 11, a light reflecting layer 13 formed on the buffer layer 14, and a reflection-enhancing layer 12 formed on the light reflecting layer 13. The light reflecting device 1 is normally installed in an optical module (not shown) and cooperates with a light source (not shown) for providing a specific reflective property to the optical module. However, the ambient light resulting from the light source may enter into the substrate 11 from other surfaces 15 of the substrate 11, which results in undesired stray light, which, in turn, results in an adverse effect on the aforesaid reflective property. A conventional approach has been proposed to eliminate the stray light, and is carried out by coating a black ink on the surfaces 15 of the substrate 11. However, the black ink tends to diminish due to vaporization after a period of use, thereby resulting in a loss of its function.

### SUMMARY OF THE INVENTION

The object of the present invention is to provide a light reflecting device that can overcome the aforesaid drawbacks associated with the prior art.

According to one aspect of this invention, there is provided a light reflecting device that comprises: a substrate having a surface; a light absorbing layer formed on the surface of the substrate; a buffer layer formed on the light absorbing layer; and a light reflecting layer formed on the buffer layer. The light absorbing layer has an extinction coefficient greater than 0.15 and a layer thickness ranging from 10 to 500 nm.

According to another aspect of this invention, there is provided a light reflecting device that comprises: a substrate having a front surface and a back surface opposite to the front surface; a buffer layer formed on the front surface of the substrate; a light-reflecting layer formed on the buffer layer; and a light absorbing layer formed on the back surface of the substrate. The light absorbing layer has an extinction coefficient greater than 0.15 and a layer thickness ranging from 10 to 500 nm.

### BRIEF DESCRIPTION OF THE DRAWINGS

Other features and advantages of the present invention will become apparent in the following detailed description of the preferred embodiments of the invention, with reference to the accompanying drawings, in which:

FIG. 1 is a fragmentary schematic view of a conventional light reflecting device;

FIG. 2 is a schematic view of the first preferred embodiment of a light reflecting device according to this invention;

FIG. 3 is a schematic view of the second preferred embodiment of the light reflecting device according to this invention;

FIG. 4 is a diagram of reflectivity (measured from a front side of the light reflecting device) vs. wavelength for examples 1 to 4 and comparative example 1; and

FIG. 5 is a diagram of reflectivity (measured from a back side of the light reflecting device) vs. wavelength for examples 1 to 4 and comparative example 1.

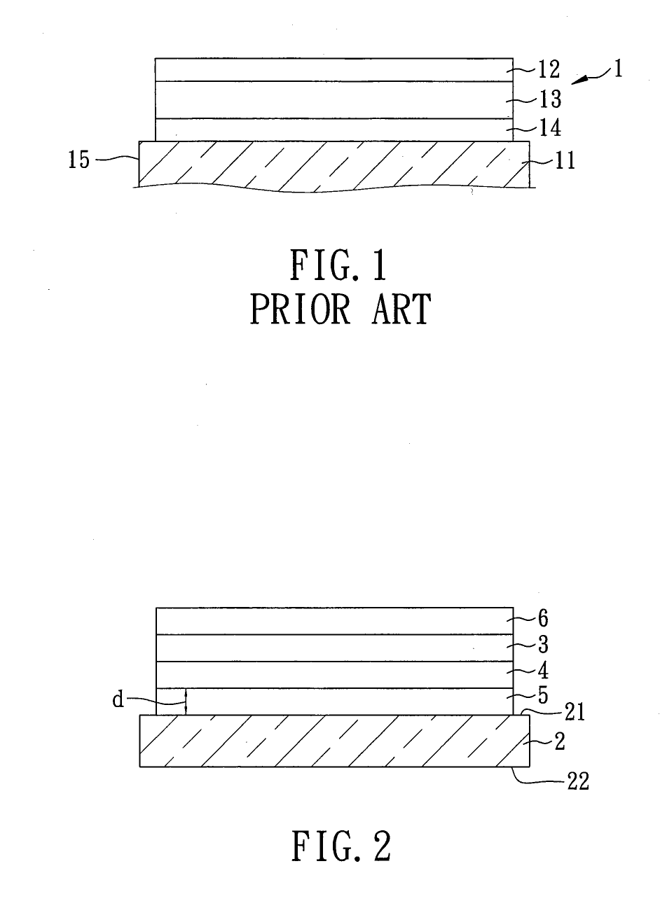

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

FIG. 2 illustrates the first preferred embodiment of a light reflecting device according to this invention for an optical module (not shown). The light reflecting device includes: a substrate 2 having a front surface 21 and a back surface 22 opposite to the front surface 21 in a normal direction relative to the substrate 2; a light absorbing layer 5 formed on the front surface 21 of the substrate 2; a buffer layer 4 formed on the light absorbing layer 5; and a light reflecting layer 3 formed on the buffer layer 4. The light absorbing layer 5 has an extinction coefficient (k) greater than 0.15 and a layer thickness (d) ranging from 10 to 500 nm so as to provide a sufficient light absorbing effect to thereby extinguish the stray light.

Preferably, a reflection-enhancing layer 6 is formed on the light reflecting layer 3.

The substrate 2 is made from a glass material or a plastic material. Preferably, the glass material has a refractive index ranging from 1.4 to 1.9 (under a wavelength of 550 nm), and contains mainly SiO₂ (60-70 wt %), CaO, Na, and B. Preferably, the plastic material has a refractive index of 1, 4 to 1.6 (under a wavelength of 550 nm), and is selected from the group consisting of Polycarbonate (PC) and Polymethyl Methacrylate (PMMA).

Preferably, the light absorbing layer 5 is made from a non-metallic material selected from the group consisting of Si, TiO₂, and Ta₂O₅. Alternatively, the light absorbing layer 5 can be made from a metallic material, and is preferably made from Ni—Cr—Fe alloy.

Preferably, the buffer layer 4 is made from a material selected from the group consisting of Al₂O₃ and SiO₂.

The layer thickness (d) of the light absorbing layer 5 mainly depends on the extinction coefficient (k) thereof. Note that the extinction coefficient (k) and the refractive index (n) of a material vary with the wavelength (λ) of the light beam to be reflected by the light reflecting device.

Table 1 shows the measured refractive indices (n) and the measured extinction coefficients (k) of silicon under different wavelengths (λ).

TABLE 1

| | Refractive | Extinction |
|---|---|---|
| Wavelength, λ | index, n | coefficient, k |
| 400 | 3.6947 | 1.7210 |
| 500 | 3.6025 | 0.5734 |
| 600 | 3.5064 | 0.1871 |
| 700 | 3.4183 | 0.9012 |

When silicon is used for the light absorbing layer 5 and when the wavelength (λ) of the light source is 520 nm, the layer thickness (d) of the light absorbing layer 5 preferably ranges from 70 to 500 nm. When the layer thickness (d) of the light absorbing layer 5 reaches 500 nm, the ambient light resulting from a light source of the optical module, which is the source of the stray light, can be substantially absorbed and extinguished. When the layer thickness (d) of the light absorbing layer 5 is less than 70 nm, absorption of the ambient light is relatively poor. In this embodiment, the layer thickness (d) of the light absorbing layer 5 preferably ranges from 70 to 90 nm.

Table 2 shows the measured refractive indices (n) and the measured extinction coefficients (k) of Ni—Cr—Fe alloy under different wavelengths (λ).

TABLE 2

| | Refractive | Extinction |
|---|---|---|
| Wavelength, λ | index, n | coefficient, k |
| 400 | 2.5001 | 2.2001 |
| 500 | 2.8903 | 2.4691 |
| 600 | 3.1469 | 2.7303 |
| 700 | 3.3351 | 2.9301 |

When Ni—Cr—Fe alloy is used for the light absorbing layer 5 and when the wavelength (λ) of the light source is 520 nm, the layer thickness (d) of the light absorbing layer 5 preferably ranges from 10 to 50 nm. When the layer thickness (d) of the light absorbing layer 5 reaches 50 nm, the ambient light can be substantially absorbed and extinguished. When the layer thickness (d) of the light absorbing layer 5 is less than 10 nm, absorption of the ambient light is relatively poor. In this embodiment, the layer thickness (d) of the light absorbing layer 5 preferably ranges from 10 to 30 nm.

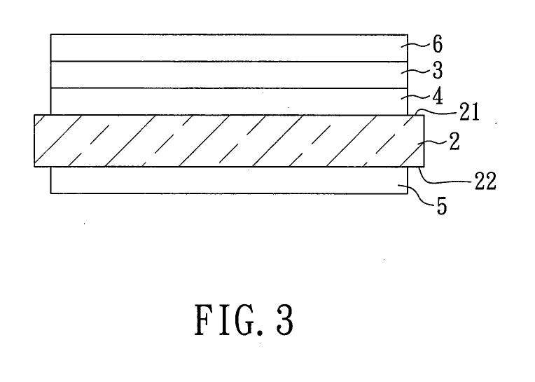

FIG. 3 illustrates the second preferred embodiment of the light reflecting device according to this invention. In this embodiment, the light reflecting device includes: a substrate 2 having a front surface 21 and a back surface 22 opposite to the front surface 21; a buffer layer 4 formed on the front surface 21 of the substrate 2; a light-reflecting layer 3 formed on the buffer layer 4; a reflection-enhancing layer 6 formed on the light reflecting layer 3; and a light absorbing layer 5 formed on the back surface 22 of the substrate 2.

The light reflecting device of this invention can be modified in a manner that it can be formed with front and rear light absorbing layers 5 on the front and back surfaces 21, 22 of the substrate 2, respectively.

The merits of the light reflecting device of this invention will become apparent with reference to the following Examples 1 to 4 and Comparative Example 1.

The layered structure of the light reflecting device of Example 1 is configured as: substrate/Si/Al₂O₃/Ag/[Al₂O₃/SiO₂/(TiO₂/SiO₂)²] (which corresponds to the substrate 2/the light absorbing layer 5/the buffer layer 4/the light reflecting layer 3/the reflection-enhancing layer 6, as illustrated in FIG. 2). The buffer layer 4, the light reflecting layer 3 and the reflection-enhancing layer 6 of this Example have a total layer thickness of 650 nm.

Example 2 differs from Example 1 in that the light absorbing layer 5 is made from Ni—Cr—Fe alloy which is commercially available from PO HUSAN ENTERPRISES CO., LTD, Taiwan and which contains 70-85 wt % of Ni, 15-25 wt % of Cr, 0-1.5 wt % of Fe, 0-2 wt % of Si, and 0-1 wt % of Mn, C, and Cu. Hence, the layered structure of Example 2 is configured as: substrate/Ni—Cr—Fe/Al₂O₃/Ag/[Al₂O₃/SiO₂/(TiO₂/SiO₂)²].

Example 3 is configured as: Si/substrate/Al₂O₃/Ag/[Al₂O₃/SiO₂/(TiO₂/SiO₂)²] (which corresponds to the light absorbing layer 5/the substrate 2/the buffer layer 4/the light reflecting layer 3/the reflection-enhancing layer 6, as illustrated in FIG. 3).

Example 4 differs from Example 3 in that the light absorbing layer 5 is made from Ni—Cr—Fe. Hence, the layered structure of Example 4 is configured as: Ni—Cr—Fe/substrate/Al₂O₃/Ag/[Al₂O₃/SiO₂/(TiO₂/SiO₂)²].

Comparative Example 1 differs from Examples 1 to 4 in that the light reflecting device of Comparative Example 1 is configured without the light absorbing layer.

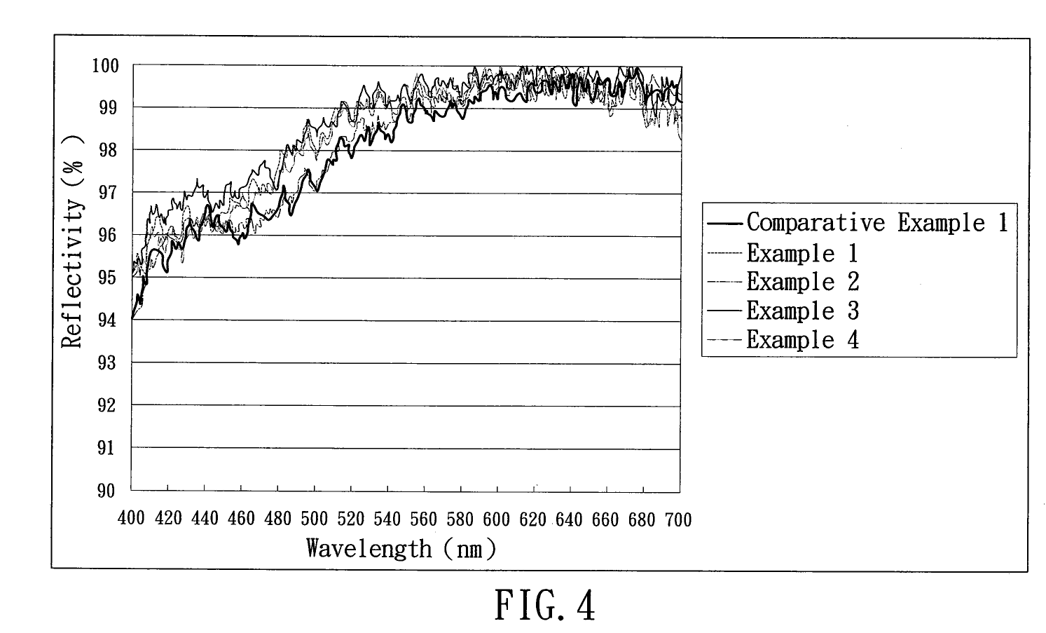

The 45° angle average reflectivity of each sample of Examples 1 to 4 and Comparative Example 1 under different wavelengths of a light beam at front and back sides of the light reflecting device was measured. The results are shown in FIGS. 4 (the front side) and 5 (the back side).

As illustrated in FIG. 4, for the front side reflectivity measurement, the 45° angle average reflectivity of the conventional light reflecting device reaches about 98.08%, while the light reflecting device of this invention reaches about 98.43%, 98.71%, 98.71%, and 98.41% for Examples 1 to 4, respectively. The results show that with the presence of the light absorbing layer 5, either formed on the front surface 21 or the back surface 22 of the substrate 2, the reflectivity of the light reflecting device of this invention is not adversely affected, and can still be maintained at a high level greater than 98% for the whole spectrum of the wavelength from 400 nm to 700 nm, which is as competitive as the conventional light reflecting device.

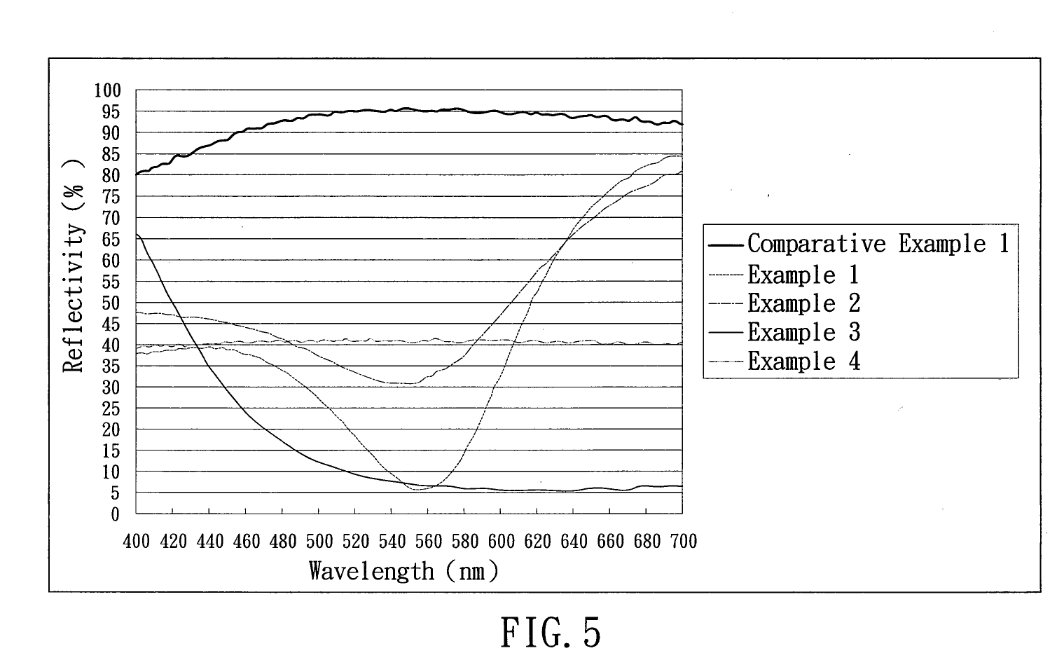

As illustrated in FIG. 5, for the back side reflectivity measurement, the 45° angle average reflectivity of the conventional light reflecting device reaches about 92.01%, while the light reflecting device of this invention reaches about 36.69%, 48.81%, 15.54%, and 40.41% for Examples 1 to 4, respectively. The results show that at least 50% of the ambient light incident from the back side of the light reflecting device of this invention can be absorbed by the light absorbing layer 5, thereby effectively extinguishing the undesired stray light.

With the inclusion of the light absorbing layer 5 in the light reflecting device of this invention, the aforesaid drawbacks associated with the prior art can be eliminated.

While the present invention has been described in connection with what are considered the most practical and preferred embodiments, it is understood that this invention is not limited to the disclosed embodiments but is intended to cover various arrangements included within the spirit and scope of the broadest interpretations and equivalent arrangements.

What is claimed is:

1. A light reflecting device with stray light extinction capability, comprising:
a substrate having a surface;
a light absorbing layer formed on said surface of said substrate;
a buffer layer formed on said light absorbing layer; and
a light reflecting layer formed on said buffer layer;
wherein said light absorbing layer has an extinction coefficient greater than 0.15 and a layer thickness ranging from 10 to 500 nm.

2. The light reflecting device of claim 1, wherein said light absorbing layer is made from a non-metallic material selected from the group consisting of Si, TiO₂, and Ta₂O₅.

3. The light reflecting device of claim 2, wherein the layer thickness of said light absorbing layer ranges from 70 to 500 nm.

4. The light reflecting device of claim 1, wherein said light absorbing layer is made from a metallic material.

5. The light reflecting device of claim 4, wherein said metallic material is Ni—Cr—Fe alloy.

6. The light reflecting device of claim 5, wherein the layer thickness of said light absorbing layer ranges from 10 to 50 nm.

7. The light reflecting device of claim 1, wherein said buffer layer is made from a material selected from the group consisting of Al₂O₃ and SiO₂.

8. The light reflecting device of claim 1, further comprising a reflection-enhancing layer formed on said light reflecting layer.

9. A light reflecting device with stray light extinction capability, comprising:
a substrate having a front surface and a back surface opposite to said front surface;
a buffer layer formed on said front surface of said substrate;
a light-reflecting layer formed on said buffer layer; and
a light absorbing layer formed on said back surface of said substrate;
wherein said light absorbing layer has an extinction coefficient greater than 0.15 and a layer thickness ranging from 10 to 500 nm.

10. The light reflecting device of claim 9, wherein said light absorbing layer is made from a non-metallic material selected from the group consisting of Si, TiO₂, and Ta₂O₅.

11. The light reflecting device of claim 10, wherein the layer thickness of said light absorbing layer ranges from 70 to 500 nm.

12. The light reflecting device of claim 9, wherein said light absorbing layer is made from a metallic material.

13. The light reflecting device of claim 12, wherein said metallic material is Ni—Cr—Fe alloy.

14. The light reflecting device of claim 13, wherein the layer thickness of said light absorbing layer ranges from 10 to 50 nm.

15. The light reflecting device of claim 9, wherein said buffer layer is made from a material selected from the group consisting of Al₂O₃ and SiO₂.

16. The light reflecting device of claim 9, further comprising a reflection-enhancing layer formed on said light reflecting layer.
